(19) United States
(12) Patent Application Publication
(10) Pub. No.: US 2006/0284234 A1
(43) Pub. Date: Dec. 21, 2006

(54) Structure of a non-volatile memory device and operation method

(76) Inventors: Tsung-Min Hsieh, Miaoli City (TW); Chien-Hsing Lee, Jhubei City (TW); Chin-Hsi Lin, Hsinchu (TW); Jhyy-Cheng Liou, Jhubei City (TW)

Correspondence Address: J C PATENTS, INC., 4 VENTURE, SUITE 250, IRVINE, CA, 92618, US

(21) Appl. No.: 11/154,378

(22) Filed: Jun. 15, 2005

(51) Int. Cl. H01L 29/76

(52) U.S. Cl. 257/314

(57) ABSTRACT

A nonvolatile memory device, including composite gate structures formed on a substrate in series along a bit line (BL) direction. Each of the composite gate structures has a first storage gate, a second storage gate, and a selection gate between the two storage gates. Each of the composite gate structures is respectively coupled to two world line (WL) connection terminals at the two storage gates and a selection terminal at the selection gate. Each of the storage gates corresponds to a memory bit cell. Multiple doped regions are in the substrate between the composite gate structures. A first selection doped region are formed in the substrate and coupled between a BL connection terminal and a first edge one of the composite gate structure. A second selection doped region is formed in the substrate and coupled between a second edge one of the composite gate structures and a voltage terminal.

### BACKGROUND OF THE INVENTION

1. Field of Invention

The present invention relates to memory device. More particularly, the present invention relates to a technology for fabricating the non-volatile memory device.

2. Description of Related Art

The non-volatile memory, such as flash memory device, allows multiple times erase and program operation inside system. As a result, flash memory is suitable to many of advance hand-held digital equipments, including solid state disks, cellar phones, digital cameras, digital movie cameras, digital voice recorders, and PDA, that are demanding a low-cost, high-density, low-power-consumption, highly reliable file memory.

Conventional technology is a NAND type flash memory with memory transistors connected in series by way of N+ impurity diffusion layer. FIG. 1A is a cross-sectional view, illustrating the semiconductor structure of the conventional NAND flash memory. In FIG. 1A, the substrate 100 usually has logic device region and the memory device region with the doped well with desired conductive type. In the following description, only the memory region is described. The substrate for example has the N-type doped well DNW 100 and then a p-type doped well TPW 102 is formed within the DNW 100. The string of NAND memory cells are then formed on the P-type well 102. Each of the memory cells 0,1, 2, . . . , n-1 has the gate structure 112, including the floating gate and the control gate, as known by the ordinary skilled artisans. The source/drain (S/D) doped region 104 is formed in the substrate 100 at each side of the gate structure. Two selection transistors 114 and 116 are coupled at the beginning and the end of the memory string. The selection transistor includes the gate electrode and the S/D regions at each side of the gate electrode. The S/D region 106 of the first selection transistor 114 is coupled to the bit line (BL) voltage while the S/D region 110 of the last selection transistor 116 is coupled to a voltage VS.

The operation of the NAND type memory is described. FIGS. 1B-1D are the operations of program, erase, and read based on the structure in FIG. 1A. In FIG. 1B, for example, the cell 0 is to be programmed. The bit line voltage is set to ground GND and applied to the S/D region 106. The S/D region 110 of the selection transistor 116 is also set to a ground voltage GND. The gate electrode of the selection transistor 114 set to a trigger voltage VCC to turn on the transistor, so as to allow the bit line voltage to pass to the doped region 105, which also serves as the S/D region 104 of the cell 0. The other cells 1, 2, . . . , n-1 are also turned on by applying a voltage ½ VPP, such as 10 V on the gate electrode, so as to pass the ground voltage at the S/D region 110 to the cell 1. The gate electrode of the cell 0 is applied with the voltage of VPP, such as 20 V. As a result, electrons are injected into the floating gate of the gate structure 112 to program the cell 0.

In FIG. 1C, when the erase operation is performed, all of the gate structures 112 are set to ground voltage GND. The selection transistor are also turned on but the S/D regions are at floating state. However, the p-type well 102 is applied a high voltage VPP. As a result, the electrons stored in the floating gate of the gate structure are driven to the substrate, and then the stored information in any one of the memory cells is erased.

In FIG. 1D, when the read operation is performed, in which the memory cell 0 is for example to be read, the gate structures 112 of the memory cells 1, 2, . . . , n-1 are applied to a pass voltage Vpass, such as 7V, so that the ground voltage at the S/D region 110 is passed to the adjacent S/D region 104 of the memory cell 0. The control gate of the gate structure 112 of the memory cell 0 is applied the ground voltage GND. However, the floating gate still carries positive voltage to turn on the memory cell 0 due to electrons being pulled out of the floating gate, if this memory cell has currently been programmed to “1”. The p-type well 102 is applied a ground voltage of GND. The BL line at the S/D region 106 then senses the conductive state of this memory string.

For the conventional NAND memory cell, it at least has several disadvantages. For example, device operation of this memory cell adopts channel FN programming and erase. The disadvantages includes, for example, the program speed is lower than that with channel hot electron. Also and, it needs an extra select transistor on source side. In addition, the cell gate between two N+ impurity layers is difficult to shrink due to short channel effect. In brief, the disadvantages includes the low programming speed due to FN tunneling, the junction to junction leak for the programmed cell, and the extra select transistor on source side of the for programming.

### SUMMARY OF THE INVENTION

The invention provides a novel non-volatile memory device, such as the flash memory device, the foregoing conventional disadvantages can at least be significantly solved. As a result, the operation speed can be effectively improved and the current leakage can be reduced. Also and, only one doped region is needed for one memory cell, so that the device size can be effectively reduced.

The present invention provides a nonvolatile memory device, which includes composite gate structures formed on a substrate in series along a bit line (BL) direction. Each of the composite gate structures has a first storage gate, a second storage gate, and a selection gate between the two storage gates. Each of the composite gate structures is respectively coupled to two world line (WL) connection terminals at the two storage gates and a selection terminal at the selection gate. Each of the storage gates corresponds to a memory bit cell. Multiple doped regions are in the substrate between the composite gate structures. A first selection doped region are formed in the substrate and coupled between a BL connection terminal and a first edge one of the composite gate structure. A second selection doped region is formed in the substrate and coupled between a second edge one of the composite gate structures and a voltage terminal.

According to the further aspect of the invention, the foregoing structure of memory device further comprises a selection transistor, coupled to the first edge one of the composite gate structures, wherein a first source/drain (S/D) region is coupled to the BL connection terminal, and a second S/D region is adjacent to the first edge one of the composite gate structures in sharing use.

According to the further aspect of the invention, the foregoing structure of memory device further comprises a drain selection gate between the first selection doped region and the first edge one of the composite gate structures.

According to the further aspect of the invention, the foregoing structure of memory device, the first selection doped region and the second selection doped region are just two doped regions without coupling to additional selection transistors.

According to the further aspect of the invention, the foregoing structure of memory device further comprises a source selection gate between the second selection doped region and the second edge one of the composite gate structures.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view, schematically illustrating the semiconductor structure of a conventional NAND type nonvolatile memory device.

FIGS. 1B-1D are the drawings, schematically illustrating the operations of read, program, and erase with respect to the structure in FIG. 1A.

FIG. 2 is a circuit drawing, schematically illustrating an array structure of the nonvolatile memory device, according to an embodiment of the invention.

FIGS. 3-5 are cross-sectional views, schematically illustrating the various semiconductor structures of a NAND type nonvolatile memory device, according the embodiment of the invention.

FIGS. 6A-6B are the drawings, schematically illustrating the program operations, according to the embodiment of the invention.

FIGS. 7A-7B are the drawings, schematically illustrating the read operations, according to the embodiment of the invention.

FIGS. 8A-8B are the drawings, schematically illustrating the erase operations, according to the embodiment of the invention.

FIGS. 9A-9C are a circuit drawings, schematically illustrating the operations of program, read and erase, according to an embodiment of the invention.

FIG. 10 is a top view, schematically illustrating a layout of the nonvolatile memory device, according to the embodiment of the invention.

FIGS. 11A-11F are cross-sectional views along the line I-I in FIG. 10, schematically illustrating the fabrication process for the nonvolatile memory device, according to the embodiment of the invention.

FIG. 12 is a cross-sectional view along the line II-II in FIG. 10, schematically illustrating the a structure for the nonvolatile memory device, according to the embodiment of the invention.

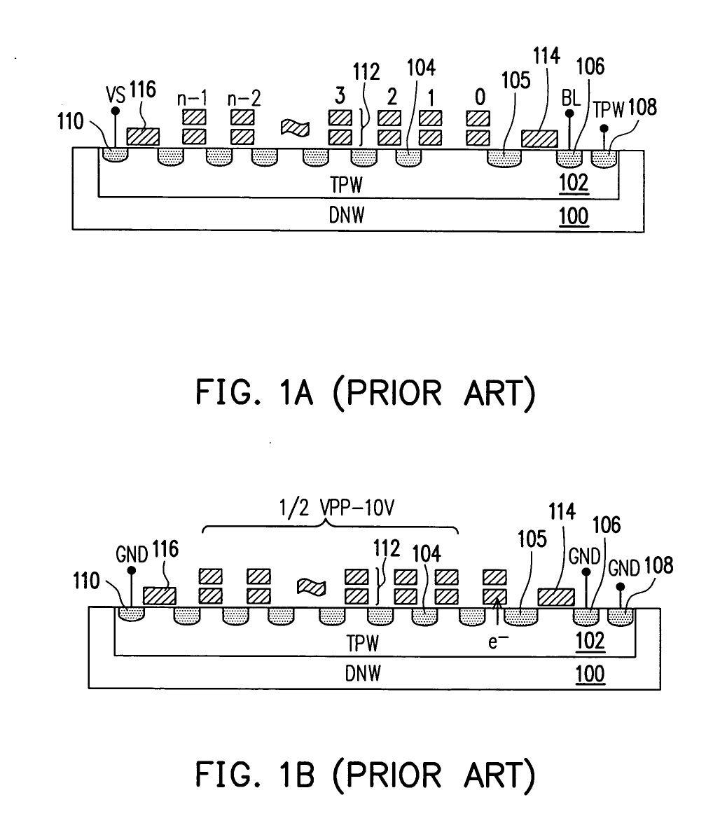

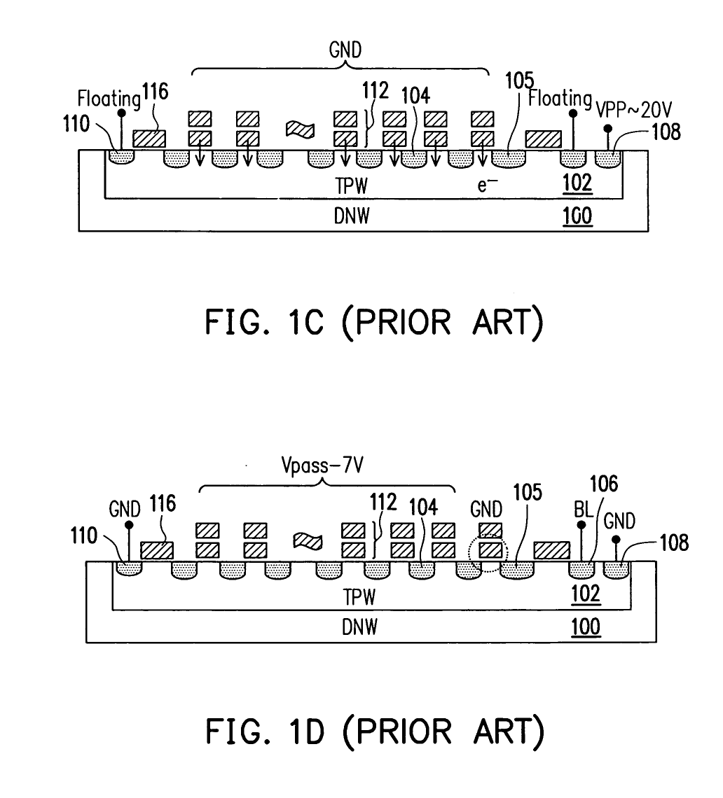

### DESCRIPTION OF THE PREFERRED EMBODIMENTS

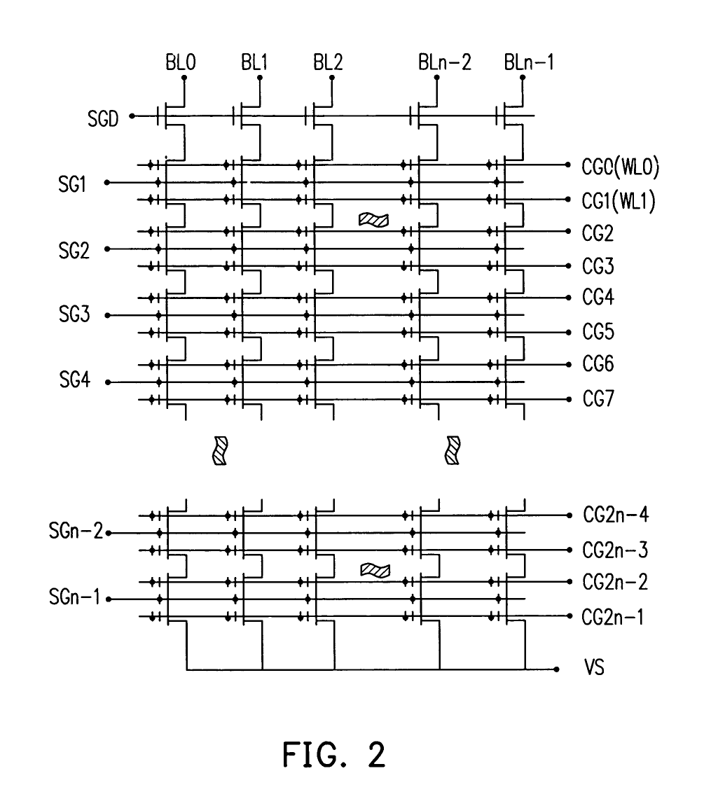

The invention is directed a novel volatile memory device. In order to perform good reliability, the structure of the memory array is proposed, as shown in FIG 2. About the general properties of the invention, the novel memory device is an NAND Type array architecture with memory transistors connected in series by way of n+ impurity layer and select gate in turn along the bit line. The advantage of this cell compared to conventional NAND memory device is that the source side hot electron can be adopted in this novel nonvolatile memory device. The source side hot electron program can provide very high program speed and low program current. The novel memory device can has one select transistor on BL side or two select transistors on both side of memory array. It is easy to shrink the cell gate due to only one impurity layer for one cell, while there are two impurity layers on both sides of cell gate for conventional NAND flash.

In FIG. 2, the memory cell employ a stack gate as the storage gate for store the information, in which the stack gate usually includes, for example, the floating gate for storing information and the control gate control the cell to drive electron in or out from the floating gate by hot carrier injection or FN mechanism. However, the storage gate structure is not limited to the stack gate structure. Any equivalent storage gate structure under the same design principle in the invention can also be used. The control gates are coupled to the corresponding word lines. For example, the control gate 0 (CG0) is coupled to the word line 0 (WL0) and the control gate 1 (CG1) is coupled to the word line 1 (WL1). In the invention, the adjacent two memory bit cells are implemented with a selection gate, such as SG1 with respect to CG0 and CG1, so that a dual-bit memory cell can be formed. The desired source/drain (S/D) regions can be applied to the bit line terminals BL0, BL1, . . . BLn-1 in a memory block, and the source terminal VS. The S/D regions are passed to the selected cell, so as to form a result equivalent to a single MOS memory cell.

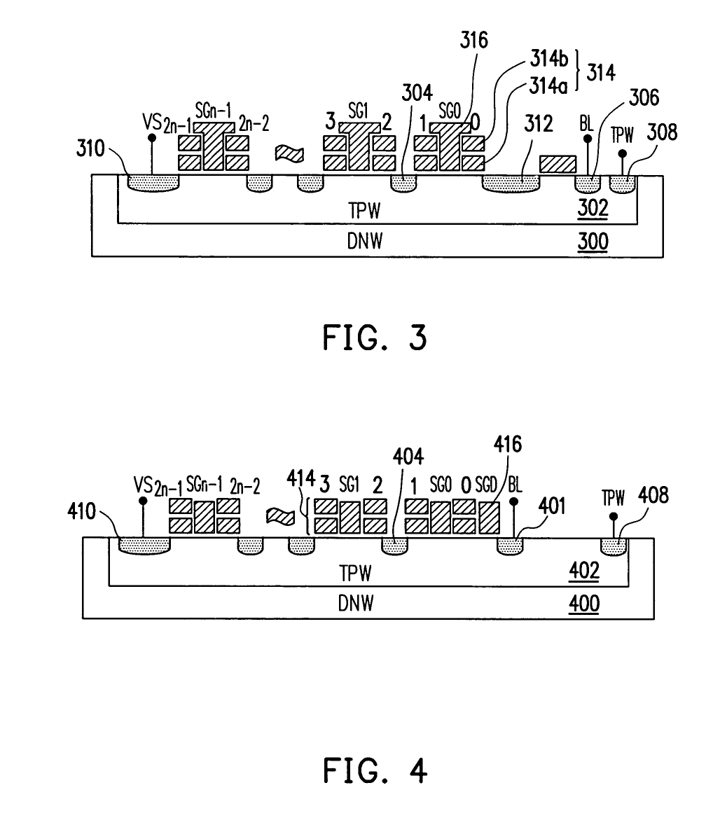

FIGS. 3-5 are cross-sectional views, schematically illustrating the various semiconductor structures of a NAND type nonvolatile memory device, according the embodiment of the invention. In FIG. 3, the substrate has the N-type doped well 300 called DNW, and a P-type doped well 302 called TPW. The N-type memory array is for example formed on the TPW 302. A well voltage terminal 308 is formed in the well 302 for supplying a desired voltage to the well 302 during operation. A selection transistor has the S/D regions 306 and 312 are the doped regions in the substrate at each side of the gate, in which the S/D doped region 306 is coupled to a bit line (BL) connection terminal to apply a bit line voltage. The S/D region 312 is in sharing use with the first edge one of the actual memory cells, such as the cell 0. A plurality of composite gate structures is formed over the substrate along a direction, called BL direction. a doped region 304 is formed between adjacent two composite gate structures. As a result, a memory string is formed. One composite gate structure includes two storage gates 314, and a selection gate (SG0, SG1, . . . , SGn-1) 316 between the two storage gates 314. The storage gate 314 can be, for example, a stack gate structure including the floating gate 314 a at the bottom portion and the control gate 314b over the floating gate 314a. Here, the dielectric layer for the necessary isolation use is not described in detail but should be known by the ordinary skill artisans. Then, the last composite gate structure, including the memory cells 2n-2, 2n-1 and the selection gate SGn-1, uses a doped region 310 as the S/D region, for coupling to a source voltage VS. Here, the selection gate structure can be, for example, a T-shape.

In FIG. 3, only one memory string, corresponding to one bit line, is shown. The control gates 314b are respectively coupled to the word lines. Two memory cells, such as cells 0 and 1, is operated with one selection gate 316, such as SG0, form a dual-bit memory cell. In other words, two memory cells with respect to one composite gate structure just use two doped regions 304. Also and, each of the doped regions 304 is shared by two composite gate structure. As a result, the number of the doped regions 304 is effectively reduced.

In FIG. 4, another semiconductor structure is shown. In comparing with semiconductor structure in FIG. 3, the selection transistor is omitted. Instead, the selection gate SGD 416, as one of the selection gates SG0, SG1, . . . SGn-1, is used to replace the selection transistor. In this manner, the doped region 401 is coupled to the BL connection terminal and is at one side of the select gate SGD. One S/D region of the selection transistor is saved. The doped region 310 is coupled to the source voltage VS connection terminal. In addition, the T-shape selection gate in FIG. 3 can be modified into a simple shape. The stack gate 414 can remain the same and the doped region 404 is formed in the substrate between the adjacent two composite gate structures.

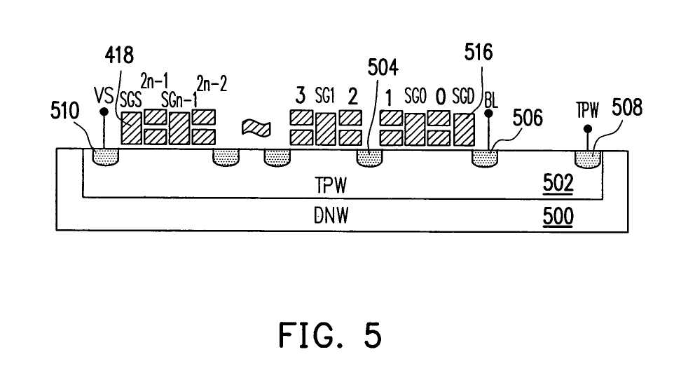

With the same circuit design, FIG. 5 further shows another semiconductor structure. The selection gate SGD 516, as one of the selection gates SG0, SG1, . . . SGn-1, is used to replace the selection transistor. In this manner, the doped region 506 is coupled to the BL connection terminal and is at one side of the select gate SGD 516. One S/D region of the selection transistor is saved. In addition, the T-shape selection gate in FIG. 3 can be modified into a simple shape. The semiconductor structure in FIG. 5 is rather similar to the semiconductor structure in FIG. 4, but the additional selection gate SGS 418 is included. The selection gate SGS 418 uses the doped region 510 as one S/D region, coupled to the source voltage terminal VS.

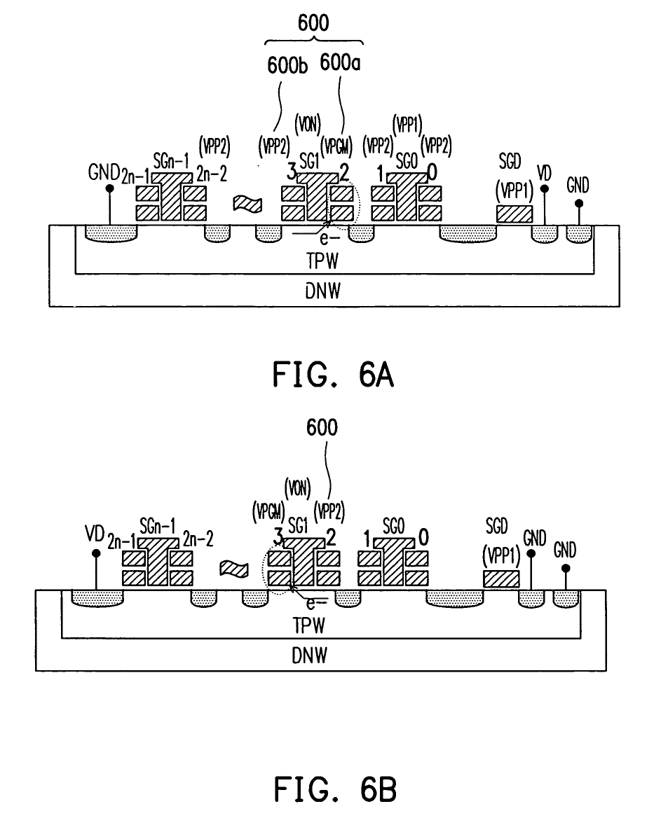

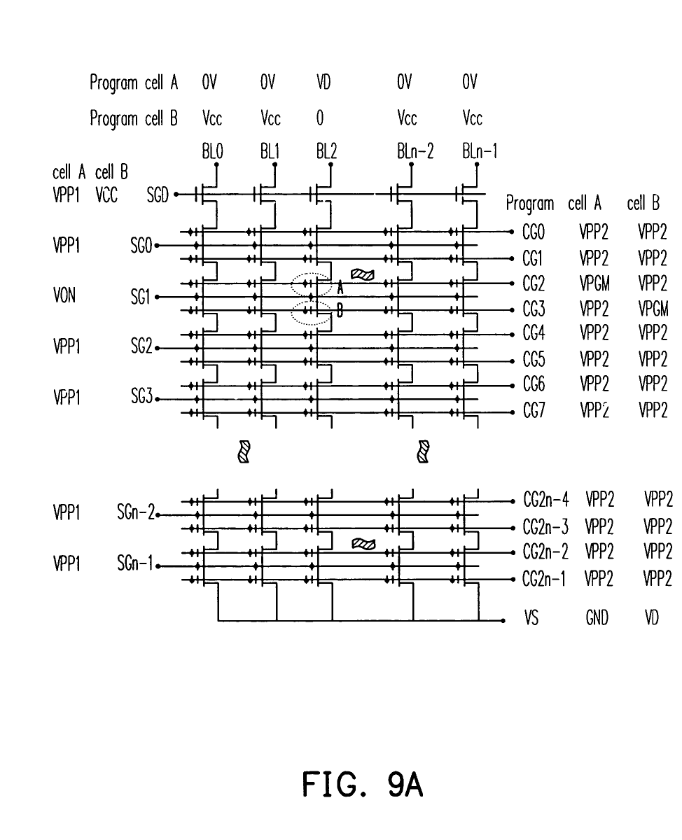

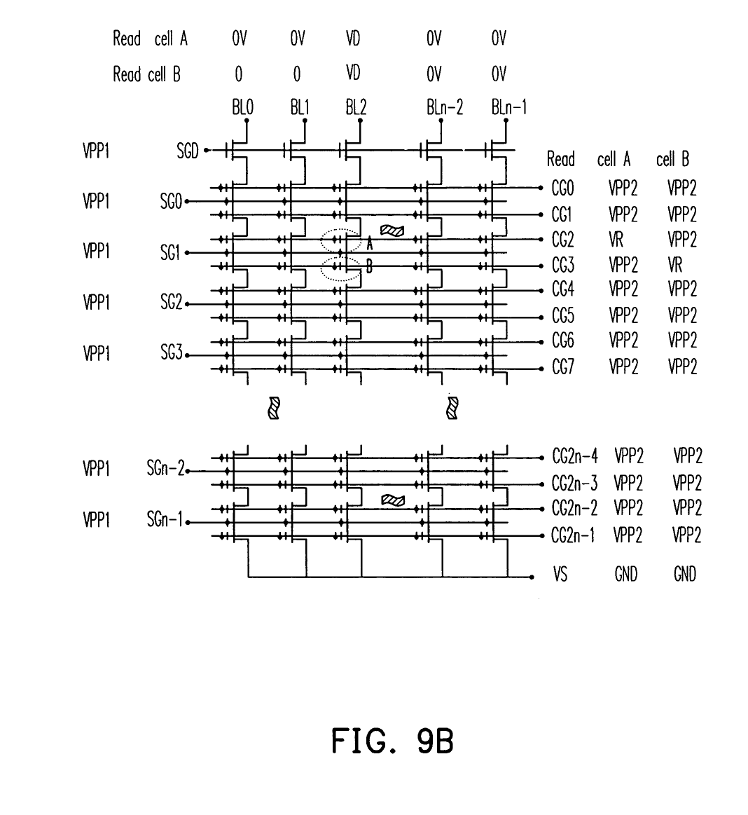

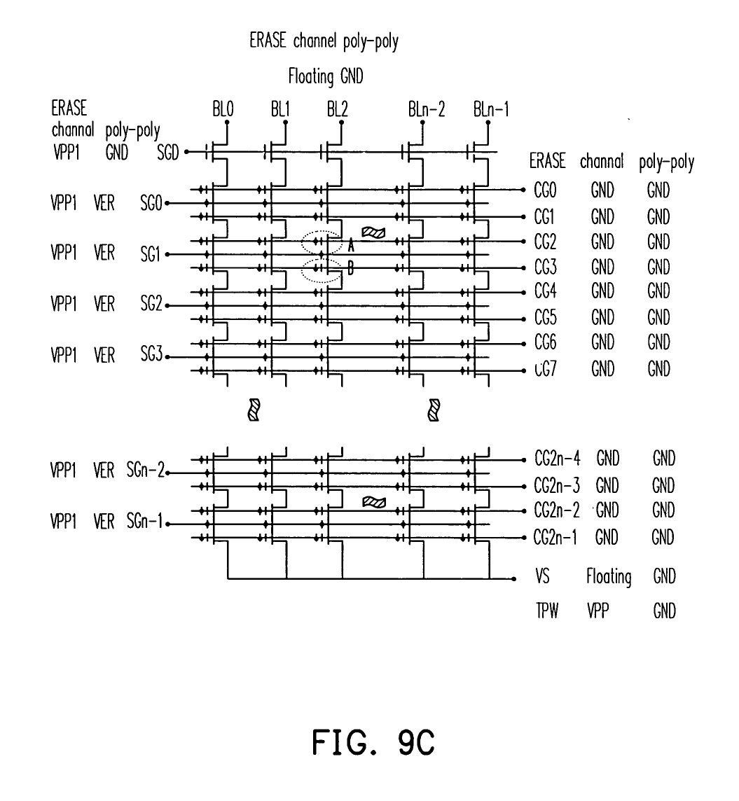

The foregoing three semiconductor structures are actually in the same circuit structure as shown in FIG. 2. For describing the operation mechanism of read, program, and erase, only the semiconductor structure in FIG. 3 is used as the example for description. FIGS. 6A-6B are the drawings, schematically illustrating the program operations, according to the embodiment of the invention. The program operation can also be referred to FIG. 9A by applying a set of programming voltages. In FIG. 6A and FIG. 9A, as described above, the invention is a dual-bit memory structure. In other words, one composite memory cell structure includes a bit cell A and a bit cell B. For example, the dual-bit memory cell 600 associating with the selection gate SG1 is selected, and the bit cell A is intended to be programmed, in which the cell 2 is to be programmed. Then, the selection gate SG1 is set to a voltage VON to turn on the selection gate, in which the voltage VON preferably is slightly greater than the threshold voltage. It is used to constrain the program current to the memory cell 2 form the source side hot electrons in program. At the same time, the other select gates are bias to VPP1 to pass BL voltage and the VS. The control gate on the memory cell 2 is pulled high to a programming voltage VPGM, while the others control gates is biased to VPP2 as to serving as the pass transistors to pass BL voltage. The corresponding BL2 of the program cell is biased to a voltage VD. The select transistor SGD is applied with a voltage VPP1 to pass the BL voltage. The source voltage (VS) is ground. At the same time, the other select gates are bias to VPP 1 to pass BL voltage and the VS. The programming electron current, as indicated by arrow, flows from VS to BL, and some hot electrons are tunneled into the floating gate of the cell 2. Due to the programming current, the hot electrons are driven into the floating gate for storing the bit data.

Likewise, in FIG. 6B, the cell B, that is, cell 3 is to be programmed. The mechanism is the same. However, the direction of the programming current is reversed, so as to program cell B. The programming voltage VPGM is applied to the cell 3. The S/D voltages are also reversed, in which the voltage of VD and ground GND are inverse. Then, the hot electrons as indicated by the arrow flow into the cell 3.

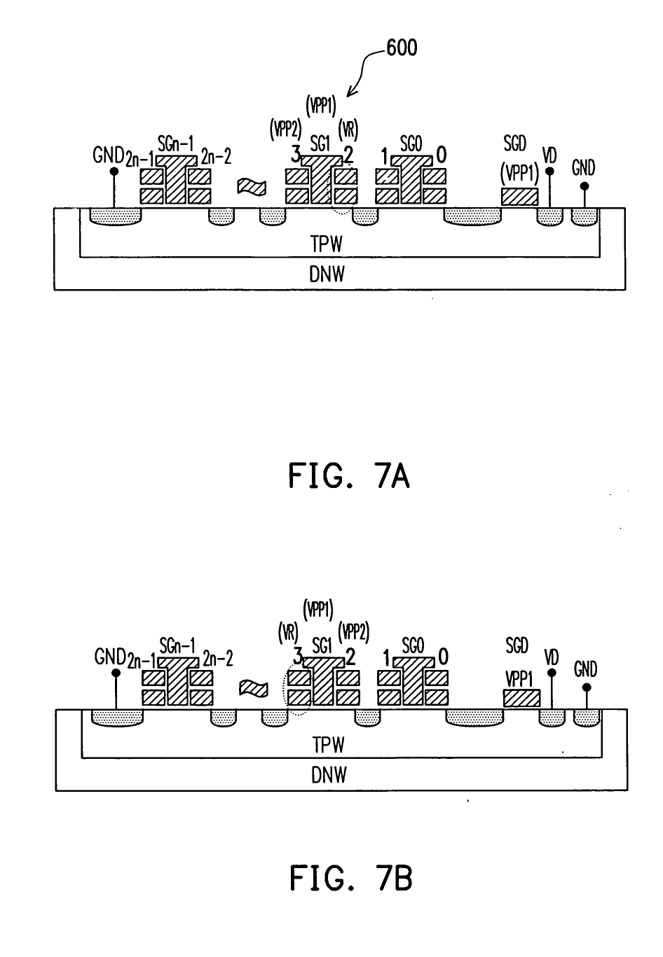

For the read operation, the cell 2 can be read by applying a set of the read voltages. In FIG. 7A and FIG. 9B, when the cell 2 is read, the control gate CG2 is, applied with a read voltage VR. At the same time, the other control gates are applied with a voltage VPP2 while all of the selection gates SG0, SG1, . . . SGn-1 are applied with the voltage VPP1, whereby the source voltage VS and the BL voltage are passed to the cell 2, to serve as the S/D regions.

Likewise, when the cell 3, that is, cell B is read, then the read voltage VR is applied to the control gate CG3. The other control gates are applied with the voltage VPP2 and all of the selection gates arc applied with the voltage VPP1, whereby the S/D voltages are passed to the cell 3.

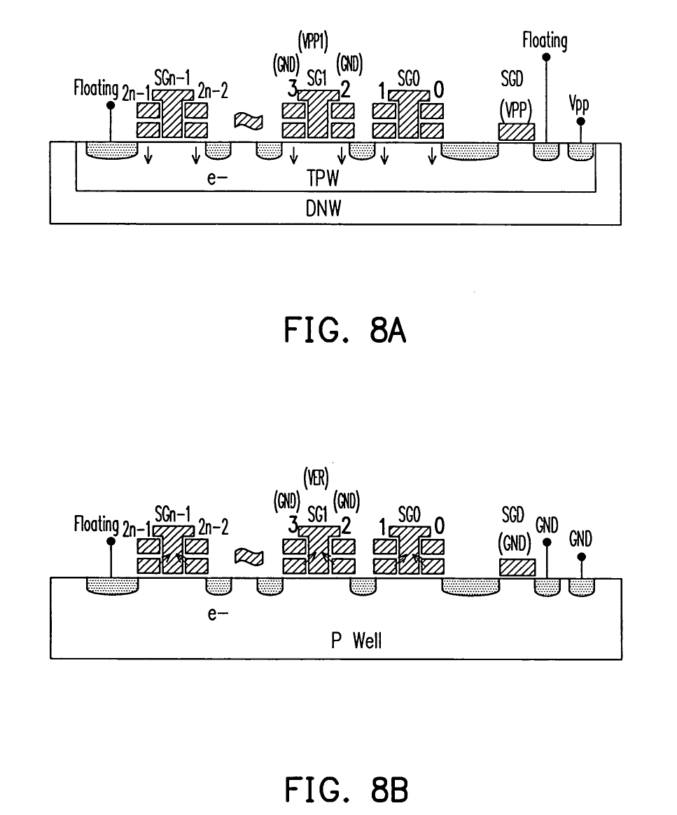

For the erase operation, it for example has two ways to erase the stored information, one is called channel erase and another one is called poly-to-poly erase. In FIG. 8A and FIG. 9C, the channel erase is shown. By applying the set of erase voltages, the electrons stored in the floating gate are driven into the substrate, as indicated by the arrow. Usually the erase operation can be applied to the whole array in a block. The voltages in FIG. 8A and FIG. 8B are only shown on the cells 2 and 3, and the other cells are identical. For the poly-to-poly erase, the electrons stored in the floating gate are driven to the selection gate.

It should be noted that the operation voltages shown above are just the example. However, the actual operation voltage can be modified according to the actual design. Table 1 also shows a preferred range for the operation voltages.

TABLE 1

| | Program CellA | Program CellB | Read Cell | Erase(channel FN) | Erase(poly-poly FN) |
|---|---|---|---|---|---|
| SDG | VPP1: 6-15 V | Vcc | VPP1: 2-10 V | VPP: 10-20 V | GND |
| Select BL | VBL: 3-7 V | GND | VBL: 0.5-2 V | Floating | GND |
| Un-select BL | GND | Vcc | GND | Floating | GND |
| Select SG | >SG Vt: 0.5-3 V | >SG Vt: 0.5-3 V | VPP1: 2-10 V | Floating or ½ VPP | VER: 10-20 V |
| Un-select SG | VPP1: 6-15 V | VPP1: 6-15 V | VPP1: 2-10 V | Floating or ½ VPP | VER: 10-20 V |
| Select CG | VPGM: 5-15 V | VPGM: 5-15 V | GND | GND | GND |
| Un-select CG | VPP2: 6-15 V | VPP2: 6-15 | VPP2: 6-15 | GND | GND |
| VS | GND | VS: 3-6 V | GND | Floating | GND |
| TPW | GND | GND | GND | VPP: 10-20 V | GND |

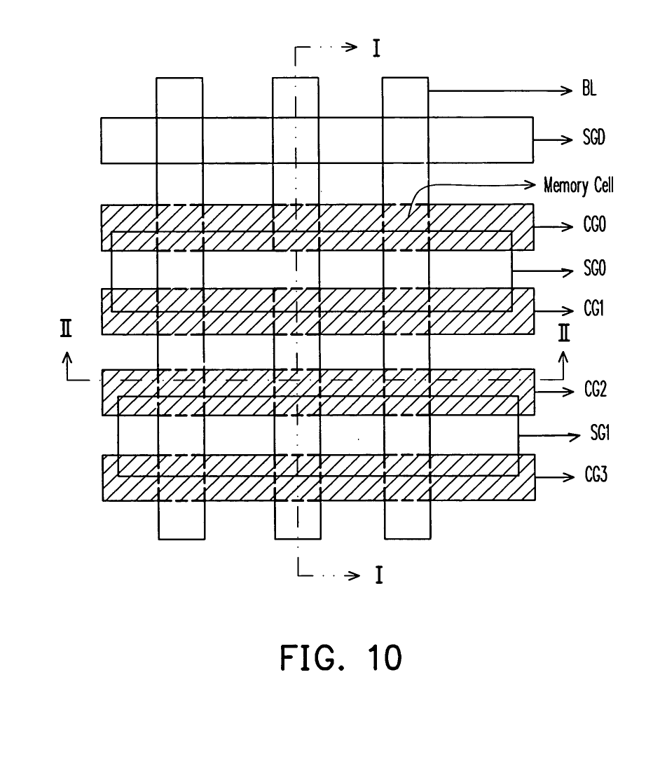

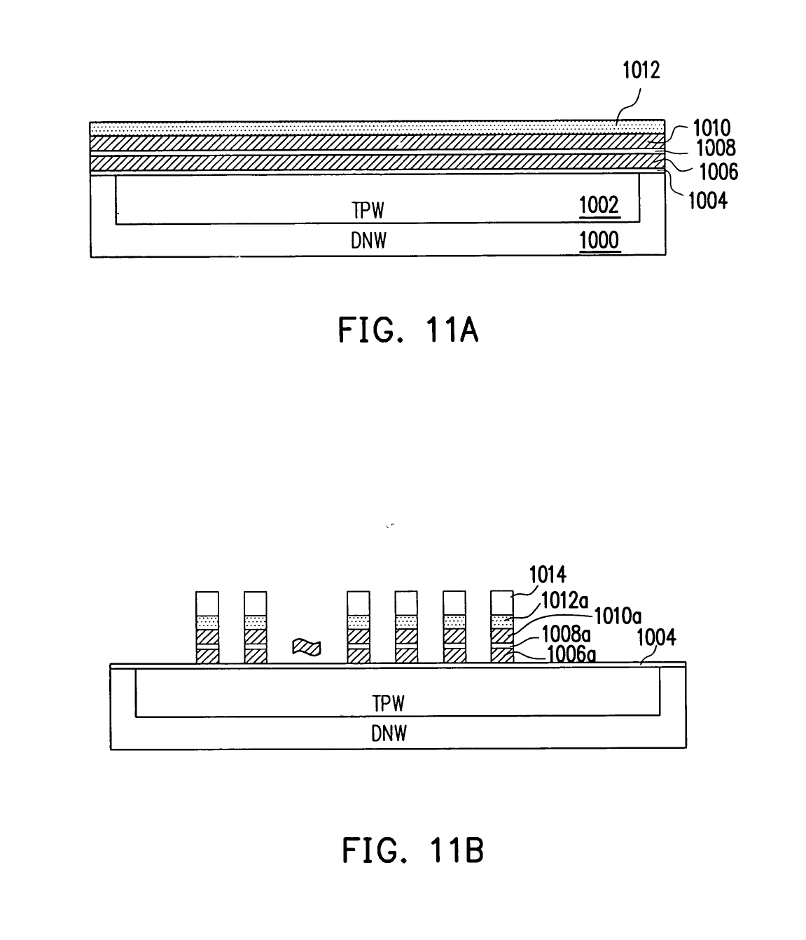

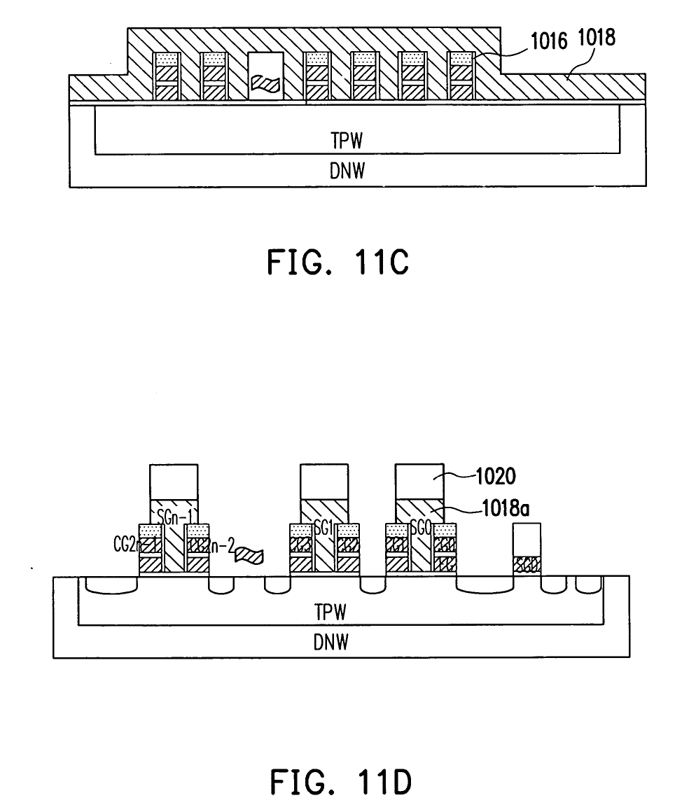

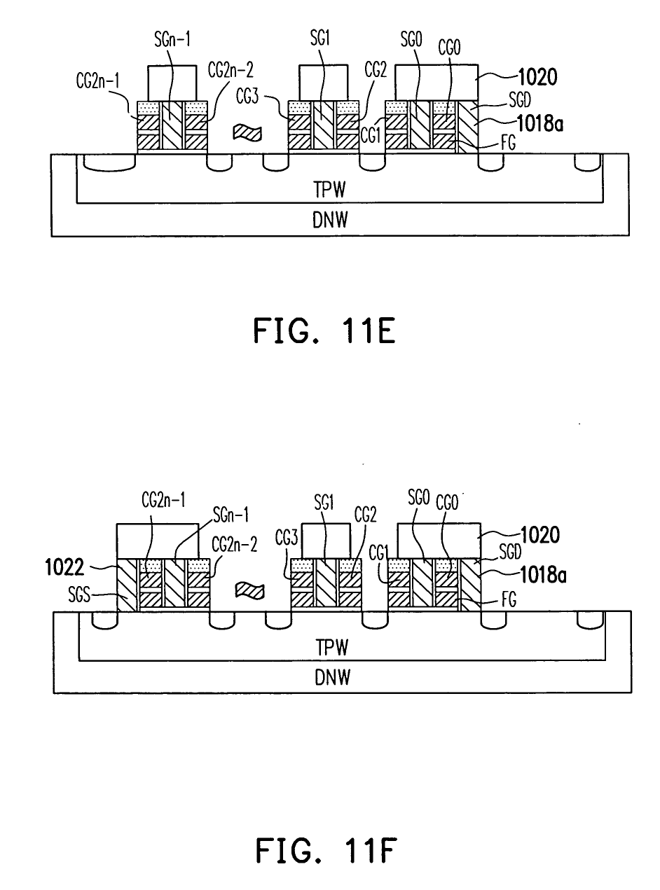

In the following descriptions, the fabrication processes are shown. FIG. 10 is a top view, schematically illustrating a layout of the nonvolatile memory device, according to the embodiment of the invention. FIGS. 11A-11F are cross-sectional views along the line I-I in FIG. 10, schematically illustrating the fabrication process for the nonvolatile memory device, according to the embodiment of the invention.

In FIG. 10, the control gates are connected by the corresponding word line as indicated by shading region. The bit line is along a direction crossing the word line direction. The selection gate is between the control gates, wherein the floating gate is only with the memory cell region covered by the control gate. In FIG. 11A, a substrate has, for example, an n-type well 1000, and a p-type well 1002 is formed in the well 1000. Here, the storage gate is shown by the stack gate, including the floating gate and the control gate. A tunneling dielectric layer 1004, a floating-gate polysilicon layer 1006, an inter-dielectric layer 1008, a control-gate polysilicon layer 1010, and a dielectric layer 1012 are sequentially formed over the substrate by deposition, such as chemical vapor deposition (CVD). The tunnel dielectric layer preferably has a thickness of about 9 nm. The inter-dielectric layer 1008 can be an oxide/nitride/oxide structure.

In FIG. 11B, the photoresist layer 1014 with a pattern is formed on the dielectric layer 1012 to serve as the etching mask. An anisotropic etching process, such as dry etching, is performed to remove the exposed portion of the foregoing stack layers, to expose the tunneling dielectric layer 1004. The proper etching ratio for different material is used preferably not etching the tunnel dielectric layer 1004. The remaining stack structure becomes the tunneling dielectric layer 1004a, the floating-gate polysilicon layer 1006a, the inter-dielectric layer 1008a, the control-gate polysilicon layer 1010a, and the dielectric layer 1012a.

In FIG. 11C, after stripping the photoresist layer 1014, a dielectric spacer 1016, such as oxide spacer is formed at sidewalls of the stacked gate. A conductive layer 1018, such as polysilicon layer 1018, is formed over the substrate by deposition, such as chemical vapor deposition (CVD). The polysilicon layer 1018 also fills the gap between the stack gate structure. Due to isolation by the dielectric layer 1012 a and the spacer 1016a, the polysilicon layer 1018 is isolated from the floating-gate polysilicon layer 1006a and the control-gate polysilicon layer 1010a.

In FIG. 11D, the photoresist layer 1020 with a pattern is formed form on the conductive layer 1018, and the etching process is performed to remove the exposed portion of the polysilicon layer 1018. The remaining portion is the polysilicon layer 1018a, which is in T-shape to serve as the selection gate SG0, SG1, . . . , SGn-1. The remaining gate structures serve as the stack gate structures CG0, CG1, . . . , CG2n-1. As a result, the portion between the stack gate structures without be covered by the photoresist layer 1020 is removed to expose the substrate. Further, an implantation process is performed to implant the dopants into substrate to serve as the doped regions, which also serve as the S/D regions in operation. The implantation process can be performed before or after the photoresist layer is stripped. Also and, the implantation can be the self-align implantation. In this embodiment, the selection transistor with the gate SGD is formed. This is equivalent to the structure in FIG. 3.

In FIG. 11E subsequent from FIG. 11C, for the structure in FIG. 4, an etching back process is performed to remove a top portion of the polysilicon layer 1018 to expose the dielectric layer 101 2 a (see FIG. 11B). Then, the polysilicon layer 1018 is patterned by photolithographic process and etching process to form the polysilicon layer 1018a in FIG. 11E. In this example, the photoresist layer 1020 covers the polysilicon layer 1018 a between the stack gate, wherein the polysilicon layer 1018 a serves as the selection gate SG0, SG 1, . . . , SGn-1. Also and, the photoresist layer 1020 also only covers on the portion indicated by SGD, which can server as a gate of the selection transistor. Then, an etching process, such as the anisotropic etching process, is performed to remove the exposed portion of the polysilicon layer 1018, and then the remaining portion is the polysilicon layer 1018a. Then, an implantation process is performed before or after the photoresist layer is stripped. Here, the implantation, process can include the self-align implantation. However, the side doped regions for coupling to the bit line and the source voltage can be formed by the usual implantation process with another photoresist mask (not shown).

In FIG. 11F subsequent from FIG. 11C, for the structures in FIG. 5, the process is similar to the process in FIG. 11E. However, the gate 1022 also remains to serve as the gate SGS. In other words, the selection transistors for the memory block uses the gates SGD and SGS in operation.

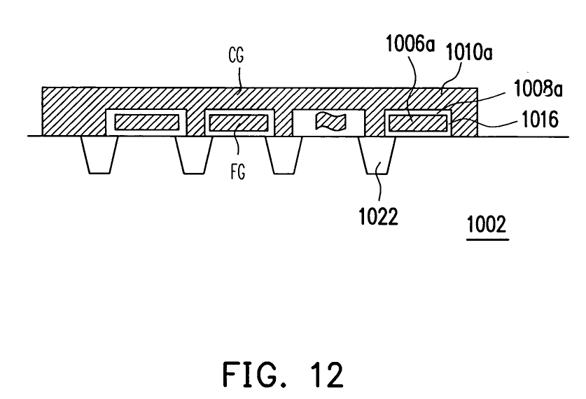

In FIG. 12, the cross-sectional view along the line II-II in FIG. 10 is shown. The control gate CG 1010a can be coupled to the word lines. Each memory cell also has the floating gate FG 1006a. The insulating dielectric structure 1016 is used to isolate the floating gate and the control gate, and also provides the tunneling dielectric layer between the floating gate the substrate. It can be known that the insulating dielectric structure 1016 includes several substructures formed in different fabrication steps.

The novel nonvolatile memory device has been proposed by using the selection gate between adjacent two storage gates. As a result, one memory can need only one doped region, that is, junction region. The selection gate can also avoid the current leakage. The operation speed, such as the programming speed, can be improved, and the device size can be reduced.

It will be apparent to those skilled in the art that various modifications and variations can be made to the structure of the present invention without departing from the scope or spirit of the invention. In view of the foregoing descriptions, it is, intended that the present invention covers modifications and variations of this invention if they fall within the scope of the following claims and their equivalents.

What is claimed is:

1. A structure of a nonvolatile memory device, comprising:
a plurality of composite gate structures formed on a substrate in series along a bit line (BL) direction, wherein each of the composite gate structures comprises a first storage gate, a second storage gate, a selection gate between the two storage gates, and an insulating layer for isolation the various gates, wherein each of the composite gate structures is respectively coupled to two world line (WL) connection terminals at the two storage gates and a selection terminal at the selection gate, wherein each of the storage gates corresponds to a memory bit cell;
a plurality of doped regions in the substrate between the composite gate structures;
a first selection doped region, formed in the substrate, coupled between a BL connection terminal and a first edge one of the composite gate structure; and
a second selection doped region, formed in the substrate, coupled between a second edge one of the composite gate structures and a voltage terminal.

2. The structure of claim 1, wherein the storage gates of the composite gate structures include a floating gate over the substrate to storage use and a control gate over the floating gate for control use.

3. The structure of claim 1, wherein the two storage gates of each of the composite gate structures form a dual-bit cell.

4. The structure of claim 3, wherein one bit of the dual-bit cell are programmed, read, or eased by applying a set of operation voltages on the nonvolatile memory device, wherein the selection gate is used to select the bit.

5. The structure of claim 1, further comprising a selection transistor, coupled to the first edge one of the composite gate structures, wherein a first source/drain (S/D) region is coupled to the BL connection terminal, and a second S/D region is adjacent to the first edge one of the composite gate structures in sharing use.

6. The structure of claim 5, wherein the second selection doped region is a S/D region of the second edge one of the composite gate structures without connecting to an additional selection transistor.

7. The structure of claim 1, further comprising a drain selection gate between the first selection doped region and the first edge one of the composite gate structures.

8. The structure of claim 7, wherein the first selection doped region and the second selection doped region are just two doped regions without coupling to additional selection transistors.

9. The structure of claim 7, further comprising a source selection gate between the second selection doped region and the second edge one of the composite gate structures.

10. The structure of claim 9, wherein the first selection doped region and the second selection doped region are just two doped regions without coupling to additional selection transistors.

11. A semiconductor structure of dual-bit memory cell, comprising:
a first storage gate structure over a substrate;
a second storage gate structure over the substrate;
a selection gate over the substrate between the first and the second storage gate structures;
a first doped region, in the substrate at an outer side of the first storage gate structure; and
a second doped region, in the substrate at an outer side of the second storage gate structure.

12. The semiconductor structure of claim 11, wherein the first storage gate structure and the second storage gate structure are a stack gate structure including a floating gate for storage and a control gate over the floating gate for control.

13. The semiconductor structure of claim 11, wherein the selection gate is used/ to select one of the first storage gate structure and the second storage gate structure in a read operation or a program operation.

14. An operation method of a nonvolatile memory device as recited in claim 1, comprising:
applying a set of reading voltages on the BL connection terminal, the voltage terminal, the WL connection terminal, the selection gate, and the storage gates, for a read operation on a selected reading cell;
applying a set of programming voltages on the BL connection terminal, the voltage terminal, the WL connection terminal, the selection gate, and the storage gates, for a program operation on a selected programming cell; and
applying a set of erasing voltages on the BL connection terminal, the voltage terminal, the WL connection terminal, the selection gate, and the storage gates, for an erase operation on a selected erasing cell.

15. The operation method of claim 14, wherein in the set of programming voltages in the program operation, the selection gate of the selected programming cell is applied with a voltage greater than a threshold voltage, so as to constrain a programming current to flow through the selected reading cell in a corresponding one of the composite gate structures.

16. The operation method of claim 14, wherein desired voltages for S/D voltages are applied at the first selection doped region and the second selection doped region, and are passed to the selected programming cell, the selected reading cell, or the selected erasing cell.

17. The operation method of claim 14, wherein, in the erase operation, all information stored in an array block of the memory bit cells is erased at the same time.
